(19) United States
(12) Patent Application Publication
(10) Pub. No.: US 2026/0143732 A1
(43) Pub. Date: May 21, 2026

(54) SEMICONDUCTOR DEVICE

(71) Applicant: SAMSUNG ELECTRONICS CO., LTD., Suwon-si (KR)

(72) Inventors: JIN-HWAN KIM, Suwon-si (KR); IN JUN HWANG, Suwon-si (KR); JOONYONG KIM, Suwon-si (KR)

(73) Assignee: SAMSUNG ELECTRONICS CO., LTD., Suwon-si (KR)

(21) Appl. No.: 19/222,502

(22) Filed: May 29, 2025

(30) Foreign Application Priority Data
Nov. 19, 2024 (KR) 10-2024-0165645

(51) Int. Cl. H10D 30/47; H10D 62/85; H10D 64/00

(52) U.S. Cl. CPC H10D 30/475; H10D 62/8503; H10D 64/112

(57) ABSTRACT

A semiconductor device includes: a barrier layer on a channel layer and including a material having a different energy band gap from that of the channel layer; source and drain electrodes on the channel layer; a gate electrode on the barrier layer between the source electrode and the drain electrode; a gate semiconductor layer between the barrier layer and the gate electrode; a first field dispersion layer between the source electrode and the drain electrode, and connected to the source electrode; a second field dispersion layer between the gate electrode and the drain electrode on the barrier layer, and connected to the first field dispersion layer; and a third field dispersion layer between the second field dispersion layer and the drain electrode on the barrier layer. An edge of the first field dispersion layer is aligned with an edge of the third field dispersion layer along a vertical direction.

### CROSS-REFERENCE TO RELATED APPLICATION

This application claims priority to Korean Patent Application No. 10-2024-0165645, filed in the Korean Intellectual Property Office on Nov. 19, 2024, the disclosure of which is incorporated by reference herein in its entirety.

### BACKGROUND

### 1. Field

The present disclosure relates to a semiconductor device.

### 2. Description of Related Art

Power semiconductor devices are semiconductor devices used to handle high voltage or high current, and perform functions such as power conversion and control in large power systems or high-output electronic devices. The power semiconductor device may be used in various fields, including transportation, such as electric vehicles, railways, and electric trams; renewable energy systems, such as solar and wind power generation; and mobile devices. The power semiconductor devices have ability and durability to handle high power, so they may handle large amounts of current and withstand high voltage. For example, the power semiconductor devices may handle voltages from hundreds of volts to thousands of volts, and currents from tens of amperes to thousands of amperes. The power semiconductor devices may improve efficiency by minimizing power loss. Additionally, the power semiconductor devices may be stably driven even in a high temperature environment.

These power semiconductor devices may be classified according to materials, and examples thereof include SiC power semiconductor devices and GaN power semiconductor devices. The unstable characteristics of silicon at high temperatures may be compensated by manufacturing the power semiconductor devices using SiC or GaN instead of existing silicon (Si). SiC power semiconductor devices may be resistant to high temperatures and have low power loss, and may be suitable for electric vehicles, renewable energy systems, etc. GaN power semiconductor devices may require high costs, but may be efficient in terms of speed, and may be suitable for high-speed charging of mobile devices.

### SUMMARY

One or more embodiments provide a semiconductor device having stable electrical characteristics and improved reliability.

According to an aspect of an embodiment, a semiconductor device includes: a channel layer; a barrier layer on the channel layer, the barrier layer including a material having a different energy band gap from that of the channel layer; a source electrode on the channel layer; a drain electrode on the channel layer; a gate electrode on the barrier layer between the source electrode and the drain electrode; a gate semiconductor layer between the barrier layer and the gate electrode; a first field dispersion layer between the source electrode and the drain electrode, the first field dispersion layer being connected to the source electrode; a second field dispersion layer between the gate electrode and the drain electrode on the barrier layer, the second field dispersion layer being connected to the first field dispersion layer; and a third field dispersion layer between the second field dispersion layer and the drain electrode on the barrier layer. An edge of the first field dispersion layer is aligned with an edge of the third field dispersion layer along a vertical direction.

According to another aspect of an embodiment, a semiconductor device includes: a channel layer; a barrier layer on the channel layer, the barrier layer including a material having a different energy band gap from that of the channel layer; a source electrode on the channel layer; a drain electrode on the channel layer; a gate electrode on the barrier layer, between the source electrode and the drain electrode; a gate semiconductor layer between the barrier layer and the gate electrode; a first field dispersion layer between the source electrode and the drain electrode, the first field dispersion layer connected to the source electrode; a second field dispersion layer between the barrier layer and the first field dispersion layer, and between the gate electrode and the drain electrode, the second field dispersion layer connected to the first field dispersion layer; and a third field dispersion layer between the barrier layer and the first field dispersion layer, and between the second field dispersion layer and the drain electrode. A single third field dispersion layer extends from a first edge of the semiconductor device to a second edge of the semiconductor device. A distance between the drain electrode and the first field dispersion layer is equal to a distance between the drain electrode and the third field dispersion layer.

According to another aspect of an embodiment, a semiconductor device includes: a channel layer including gallium nitride; a barrier layer on the channel layer and including aluminum gallium nitride; a source electrode on the channel layer; a drain electrode on the channel layer; a gate electrode on the barrier layer, between the source electrode and the drain electrode; a gate semiconductor layer between the barrier layer and the gate electrode, the gate semiconductor layer including gallium nitride doped with a p-type impurity; a first protective layer on the barrier layer, the first protective layer at least partially covering the gate electrode; a second protective layer on the first protective layer; a first field dispersion layer on the second protective layer, wherein the first field dispersion layer overlaps the gate electrode along a vertical direction, and is integrally formed with the source electrode; a second field dispersion layer between the first protective layer and the second protective layer, wherein the second field dispersion layer overlaps the first field dispersion layer along the vertical direction and includes titanium nitride; and a third field dispersion layer between the first protective layer and the second protective layer, and between the second field dispersion layer and the drain electrode, wherein the third field dispersion layer includes titanium nitride. A distance from a side surface of the gate electrode to a side surface of the first field dispersion layer is equal to a distance from a side surface of the gate electrode to a side surface of the third field dispersion layer.

According to one or more embodiments, reliability of a semiconductor device may be improved.

### BRIEF DESCRIPTION OF DRAWINGS

The above and other aspects and features will be more apparent from the following description of example embodiments with reference to the attached drawings, in which:

FIG. 1 illustrates a top plan view of a semiconductor device according to an embodiment.

FIG. 2 and FIG. 3 each illustrate a cross-sectional view taken along a line A-A′ of FIG. 1 according to some embodiments.

FIG. 4 illustrates a top plan view of a region S1 of FIG. 2 according to an embodiment.

FIG. 5 to FIG. 9 illustrate top plan views corresponding to a region S1 in FIG. 1, showing semiconductor devices according to some embodiments.

FIG. 10 illustrates a cross-sectional view corresponding to A-A′ of FIG. 1, showing a semiconductor device according to some embodiments.

FIG. 11 to FIG. 14 each illustrate a top plan view showing a semiconductor device according to some embodiments.

FIG. 15 illustrates a cross-sectional view taken along a line B-B′ of FIG. 14 according to an embodiment.

### DETAILED DESCRIPTION

Hereinafter, embodiments will be described more fully with reference to the accompanying drawings. As those skilled in the art would realize, the described embodiments may be modified in various different ways without departing from the spirit or scope of the present disclosure.

To clearly describe the present disclosure, parts that are irrelevant to the description may be omitted, and like numerals refer to like or similar components throughout the specification.

Further, sizes and thicknesses of constituent members shown in the accompanying drawings may be arbitrarily given for better understanding and ease of description. In the drawings, the thicknesses of layers, areas, films, panels, regions, etc., may be exaggerated for clarity. Therefore, embodiments are not limited to the illustrated sizes and thicknesses.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” indicates positioned on or below the object portion, and does not necessarily indicate positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Further, throughout the specification, the phrase “in a plan view” means when an object portion is viewed from above, and the phrase “in a cross-sectional view” means when a cross-section taken by vertically cutting an object portion is viewed from the side.

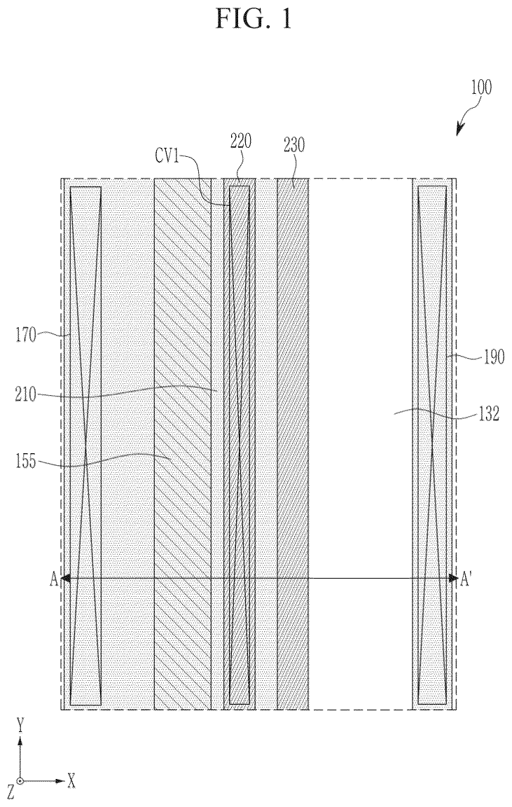

Hereinafter, a semiconductor device according to an embodiment will be described with reference to FIG. 1 to FIG. 4.

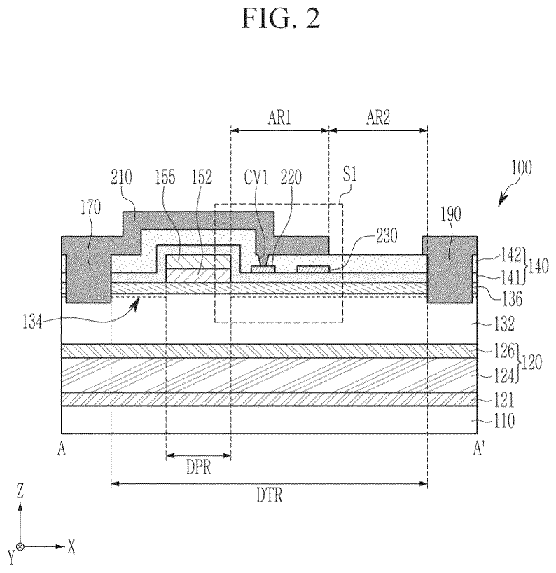

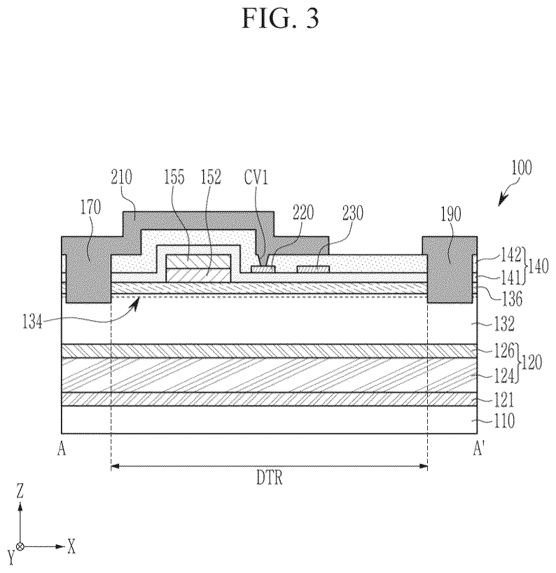

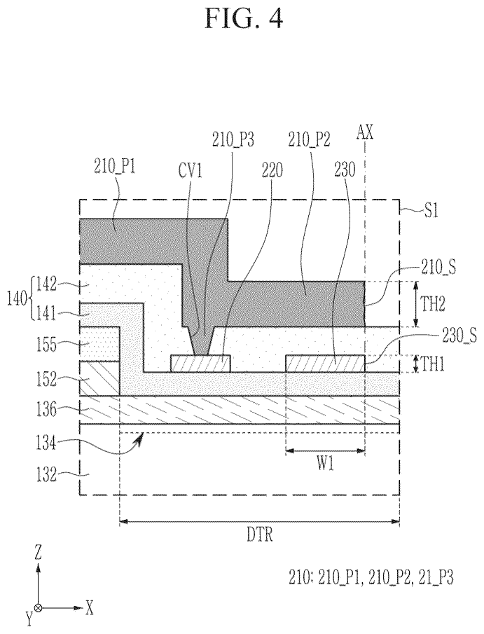

FIG. 1 illustrates a top plan view of a semiconductor device according to an embodiment. FIG. 2 and FIG. 3 each illustrate a cross-sectional view taken along a line A-A′ of FIG. 1. FIG. 4 illustrates a top plan view of a region S1 of FIG. 2. FIG. 2 shows a case where the semiconductor device 100 according to an embodiment is in an off state, and

FIG. 3 shows the semiconductor device 100 according to an embodiment in an on state.

Referring to FIGS. 1 to 4, the semiconductor device 100 according to an embodiment may include a channel layer 132, a barrier layer 136 positioned on the channel layer 132, a gate electrode 155 positioned on the barrier layer 136, a gate semiconductor layer 152 positioned between the barrier layer 136 and the gate electrode 155, a source electrode 170 and a drain electrode 190 positioned on opposite sides of the gate electrode 155 and connected to the channel layer 132, a first field dispersion layer 210 positioned between the source electrode 170 and the drain electrode 190 and electrically connected to the source electrode 170, a second field dispersion layer 220 positioned between the gate electrode 155 and the drain electrode 190, and a third field dispersion layer 230 positioned between the second field dispersion layer 220 and the drain electrode 190.

The channel layer 132 is a layer that forms a channel between the source electrode 170 and the drain electrode 190, and a two-dimensional electron gas (2 DEG) 134 may be positioned inside the channel layer 132. The two-dimensional electron gas 134 is a charge transport model used in solid physics, and refers to a group of electrons that can move freely in two dimensions (e.g., the x direction and the Y direction which extend along an X-Y plane) but cannot move in another dimension (e.g., the Z direction) and are tightly bound within the two dimensions. In this regard, the two-dimensional electron gas 134 may exist in a two-dimensional paper-like form within a three-dimensional space. This two-dimensional electron gas 134 may mainly appear in a semiconductor heterojunction structure, and in the semiconductor device 100 according to an embodiment, it may occur at an interface between the channel layer 132 and the barrier layer 136. For example, the two-dimensional electron gas 134 may be generated in a portion adjacent to the barrier layer 136 within the channel layer 132.

The channel layer 132 may include one or more materials selected from Group III-V materials, e.g., nitrides containing Al, Ga, In, B, or a combination thereof. The channel layer 132 may be formed as a single layer or multiple layers. The channel layer 132 may be AlₓIn_{y}Ga_{1-x-y}N(0≤x≤1, 0≤y≤1, and x+y≤1). For example, the channel layer 132 may include AlN, GaN, InN, InGaN, AlGaN, AlInN, AlInGaN, or a combination thereof. The channel layer 132 may be a layer doped with impurities or a layer undoped with impurities. A thickness of the channel layer 132 may be about several hundred nm or less.

The channel layer 132 may be positioned on the substrate 110, and a seed layer 121 and a buffer layer 120 may be disposed between the substrate 110 and the channel layer 132. The substrate 110, the seed layer 121, and the buffer layer 120 are layers used to form the channel layer 132, and may be omitted in some cases. For example, when a substrate made of GaN is used as the channel layer 132, at least one of the substrate 110, the seed layer 121, or the buffer layer 120 may be omitted. Considering that a price of a substrate made of GaN is relatively high, the channel layer 132 including GaN may be grown using the substrate 110 made of Si. In this case, as a lattice structure of Si and a lattice structure of GaN are different, it may not be easy to grow the channel layer 132 directly on the substrate 110. Accordingly, the seed layer 121 and the buffer layer 120 may first be grown on the substrate 110, and then the channel layer 132 may be grown on the buffer layer 120. In addition, at least one of the substrate 110, the seed layer 121, or the buffer layer 120 may be removed during manufacturing, and not be included in a final structure of the semiconductor device 100 after being used in a manufacturing process.

The substrate 110 may include a semiconductor material. For example, the substrate 110 may include sapphire, Si, SiC, AlN, GaN, or a combination thereof. The substrate 110 may be a silicon on insulator (SOI) substrate. However, a material of the substrate 110 is not limited thereto, and the substrate 110 may include different materials. In some cases, the substrate 110 may include an insulating material. For example, several layers including a channel layer 132 may be first formed on a semiconductor substrate, and then the semiconductor substrate may be removed and replaced with an insulating substrate.

The seed layer 121 may be disposed directly on the substrate 110. However, embodiments are not limited thereto, and another predetermined layer may be further disposed between the substrate 110 and the seed layer 121. The seed layer 121 is a layer that serves as a seed for growing the buffer layer 120, and may be made of a crystal lattice structure that serves as a seed for the buffer layer 120. The buffer layer 120 may be disposed directly on the seed layer 121. However, embodiments are not limited thereto, and another predetermined layer may be further disposed between the seed layer 121 and the buffer layer 120. The seed layer 121 may include one or more materials selected from Group III-V materials, e.g., nitrides containing Al, Ga, In, B, or a combination thereof. The seed layer 121 may be AlₓIn_{y}Ga_{1-x-y}N(0≤x≤1, 0≤y≤1, and x+y≤1). For example, the seed layer 121 may include AlN, GaN, InN, InGaN, AlGaN, AlInN, AlInGaN, or a combination thereof.

The buffer layer 120 may be disposed on the seed layer 121. The buffer layer 120 may be disposed between the seed layer 121 and the channel layer 132. The buffer layer 120 may be a layer to alleviate a difference in lattice constant and thermal expansion coefficient between the seed layer 121 and the channel layer 132, or to prevent leakage current from flowing through the channel layer 132. The buffer layer 120 may include one or more materials selected from Group III-V materials, e.g., nitrides containing Al, Ga, In, B, or a combination thereof. The buffer layer 120 may be AlₓIn_{y}Ga_{1-x-y}N(0≤x≤1, 0≤y≤1, and x+y≤1). For example, the buffer layer 120 may include AlN, GaN, InN, InGaN, AlGaN, AlInN, AlInGaN, or a combination thereof.

The buffer layer 120 of the semiconductor device 100 according to an embodiment may include a superlattice layer 124 positioned on the seed layer 121, and a high-resistance layer 126 positioned on the superlattice layer 124. The superlattice layer 124 and the high-resistivity layer 126 may be sequentially positioned on the substrate 110.

The superlattice layer 124 may be positioned on the seed layer 121. The superlattice layer 124 may be positioned directly on the seed layer 121. However, embodiments are not limited thereto, and another predetermined layer may be further disposed between the seed layer 121 and the superlattice layer 124. The superlattice layer 124 may be a layer to alleviate the difference in lattice constant and coefficient of thermal expansion between the substrate 110 and the channel layer 132, to alleviate tensile stress and compressive stress thus-generated between the substrate 110 and the channel layer 132, and to alleviate the stress between the entire layers formed by growth in a final structure of the semiconductor device 100 according to an embodiment. The superlattice layer 124 may include one or more materials selected from Group III-V materials, e.g., nitrides containing Al, Ga, In, B, or a combination thereof. The superlattice layer 124 may be AlₓIn_{y}Ga_{1-x-y}N(0≤x≤1, 0≤y≤1, and x+y≤1). For example, the superlattice layer 124 may include AlN, GaN, InN, InGaN, AlGaN, AlInN, AlInGaN, or a combination thereof.

In an embodiment, the superlattice layer 124 may be formed of multiple alternating layers containing different materials. For example, the superlattice layer 124 may have a structure in which a layer made of AlGaN and a layer made of AlN are repeatedly stacked. That is, AlGaN/AlN/AlGaN/AlN/AlGaN/AlN may be sequentially stacked to form the superlattice layer. A number of AlGaN layers and GaN that make up the superlattice layer 124 may be varied, and a material that makes up the superlattice layer 124 may be varied. As another example, the superlattice layer 124 may have a structure in which a layer made of AlGaN and a layer made of GaN are repeatedly stacked. That is, AlGaN/GaN/AlGaN/GaN/AlGaN/GaN may be sequentially stacked to form the superlattice layer. In an embodiment, when the superlattice layer 124 includes GaN, InN, AlGaN, AlInN, InGaN, AlN, AlInGaN, or a combination thereof, the superlattice layer 124 may have n-type semiconductor characteristics in which the concentration of electrons is greater than the concentration of holes, but embodiments are not limited thereto.

The high-resistance layer 126 may be positioned on the superlattice layer 124. The high-resistance layer 126 may be positioned directly on the superlattice layer 124. However, embodiments are not limited thereto, and another predetermined layer may be further positioned between the superlattice layer 124 and the high-resistance layer 126. The high-resistance layer 126 may be positioned between the superlattice layer 124 and the channel layer 132. The high-resistance layer 126 may be a layer that prevents the semiconductor device 100 according to an embodiment from deteriorating by preventing a leakage current from flowing through the channel layer 132. The high-resistance layer 126 may be made of a low-conductivity material to electrically insulate the substrate 110 and the channel layer 132. The high-resistance layer may include one or more materials selected from Group III-V materials, e.g., nitrides containing Al, Ga, In, B, or a combination thereof. The high-resistance layer 126 may be AlₓIn_{y}Ga_{1-x-y}N(0≤x≤1, 0≤y≤1, and x+y≤1). For example, the high-resistance layer 126 may include AlN, GaN, InN, InGaN, AlGaN, AlInN, AlInGaN, or a combination thereof. The high-resistance layer 126 may be formed as a single layer or multiple layers.

The semiconductor device 100 according to an embodiment may further include a barrier layer 136 positioned on the channel layer 132.

The barrier layer 136 may be disposed on the channel layer 132. The barrier layer 136 may be disposed directly on the channel layer 132. However, embodiments are not limited thereto, and another predetermined layer may be further disposed between the channel layer 132 and the barrier layer 136. A region of the channel layer 132 that overlaps the barrier layer 136 between the source electrode 170 and the drain electrode 190 may be a drift region DTR. The drift region DTR may be positioned between the source electrode 170 and the drain electrode 190. The drift region DTR may refer to a region to which carriers move when a potential difference occurs between the source electrode 170 and the drain electrode 190.

The semiconductor device 100 according to an embodiment may be controlled to an on state or an off state depending on whether a voltage is applied to the gate electrode 155 and/or magnitude of the voltage applied to the gate electrode 155, and accordingly movement of carriers may be achieved or blocked in the drift region DTR.

The barrier layer 136 may include one or more materials selected from Group III-V materials, e.g., nitrides containing Al, Ga, In, B, or a combination thereof. The barrier layer 136 may be AlₓIn_{y}Ga_{1-x-y}N(0≤x≤1, 0≤y≤1, and x+y≤1). The barrier layer 136 may include GaN, InN, AlGaN, AlInN, InGaN, AlN, AlInGaN or a combination thereof. An energy band gap of the barrier layer 136 may be adjusted by controlling a composition ratio of Al and/or In. The barrier layer 136 may be doped with a predetermined impurity. In this case, the impurity doped in the barrier layer 136 may be a p-type impurity capable of providing a hole. For example, impurity doped in the barrier layer 136 may be magnesium (Mg). A threshold voltage, on-resistance, etc., of the semiconductor device 100 according to an embodiment may be controlled by increasing or decreasing an impurity doping concentration of the barrier layer 136.

The barrier layer 136 may include a semiconductor material with characteristics that are different from those of the channel layer 132. The barrier layer 136 may be different from the channel layer 132 in at least one of a polarization characteristic, an energy band gap, or a lattice constant. For example, the barrier layer 136 may include a material having a different energy band gap than that of the channel layer 132. In this case, the barrier layer 136 may have a higher energy band gap than the channel layer 132, and may have a higher electrical polarization rate than the channel layer 132. The two-dimensional electron gas 134 may be induced in the channel layer 132 having a relatively low electrical polarization rate by the barrier layer 136. In this regard, the barrier layer 136 may also be referred to as a channel supply layer or a two-dimensional electron gas supply layer. The two-dimensional electron gas 134 may be formed within a portion of the channel layer 132 positioned below an interface between the channel layer 132 and the barrier layer 136. The two-dimensional electron gas 134 may have very high electron mobility.

The barrier layer 136 may be formed as a single layer or multiple layers. When the barrier layer 136 is made of multiple layers, materials of each of the layers constituting the multiple layers may have different energy band gaps. In this case, the various layers constituting the barrier layer 136 may be arranged so that an energy band gap increases as the layers approach the channel layer 132.

The gate electrode 155 may be positioned on the barrier layer 136. The gate electrode 155 may overlap some region of the barrier layer 136 in the third direction (Z direction). The gate electrode 155 may overlap a portion of the drift region DTR of the channel layer 132 in the third direction (Z direction). The gate electrode 155 may be positioned between the source electrode 170 and the drain electrode 190. The gate electrode 155 may be spaced apart from the source electrode 170 and the drain electrode 190. For example, the gate electrode 155 may be positioned closer to the source electrode 170 than the drain electrode 190. That is, a separation distance between the gate electrode 155 and the source electrode 170 may be smaller than a separation distance between the gate electrode 155 and the drain electrode 190, but embodiments are not limited thereto. In an embodiment, the gate electrode 155 may overlap a first field dispersion layer 210 to be described later in the third direction (Z direction), and may not overlap a second field dispersion layer 220 to be described later and a third field dispersion layer 230 to be described later in the third direction (Z direction). Herein, the third direction (Z direction) may indicate a thickness direction and a vertical direction of the channel layer 132.

The gate electrode 155 may include a conductive material. For example, the gate electrode 155 may include a metal, a metal alloy, a conductive metal nitride, a metal silicide, a doped semiconductor material, a conductive metal oxide, or a conductive metal nitride. For example, the gate electrode 155 may include a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride. (TiAlN), a tantalum aluminum nitride (TaAlN), a tungsten nitride (WN), ruthenium (Ru), titanium aluminum (TiAl), a titanium aluminum carbonizationnitride (TiAlC—N), a titanium aluminum carbide (TiAlC), a titanium carbide (TiC), a tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), a molybdenum nitride (MoN), molybdenum carbide (MoC), a tungsten carbide (WC), rhodium (Rh), palladium (Pd), iridium (Ir), osmium (Os), silver (Ag), gold (Au), zinc (Zn), vanadium (V), or a combination thereof. but is not limited thereto. The gate electrode 155 may be formed as a single layer or multiple layers.

In an embodiment, the semiconductor device may further include a hard mask layer positioned on the gate electrode 155. The hard mask layer may be a hard mask used when patterning the gate electrode material layer and/or the gate semiconductor layer in a process of forming the gate electrode 155. However, the hard mask layer may be removed depending on an etching condition during etching of a gate electrode material layer and/or a gate semiconductor layer or a cleaning condition after etching. For example, the hard mask layer may include a silicon oxide, a silicon nitride, a silicon oxynitride, or a combination thereof.

The gate semiconductor layer 152 may be positioned between the barrier layer 136 and the gate electrode 155. That is, the gate semiconductor layer 152 may be positioned on the barrier layer 136, and a gate electrode 155 may be positioned on the gate semiconductor layer 152. The gate electrode 155 may be in Schottky contact or ohmic contact with the gate semiconductor layer 152. The gate semiconductor layer 152 may overlap the gate electrode 155 in the third direction (Z direction). In this case, the gate semiconductor layer 152 may completely overlap the gate electrode 155 in the third direction (Z direction), and an upper surface of the gate semiconductor layer 152 may be entirely covered by the gate electrode 155. That is, the gate semiconductor layer 152 may have substantially a same planar shape as that of the gate electrode 155. However, embodiments are not limited thereto, and the gate electrode 155 may be positioned to cover at least a portion of the gate semiconductor layer 152. For example, a portion of the gate semiconductor layer 152 may not be covered by the gate electrode 155.

The gate semiconductor layer 152 may be disposed between the source electrode 170 and the drain electrode 190. The gate semiconductor layer 152 may be spaced apart from the source electrode 170 and the drain electrode 190. The gate semiconductor layer 152 may be positioned closer to the source electrode 170 than the drain electrode 190. That is, a separation distance between the gate semiconductor layer 152 and the source electrode 170 may be smaller than a separation distance between the gate semiconductor layer 152 and the drain electrode 190, but embodiments are not limited thereto.

In an embodiment, the gate semiconductor layer 152 may overlap the gate electrode 155 in the third direction (Z direction). For example, the gate semiconductor layer 152 may completely overlap the gate electrode 155 in the third direction (Z direction). For example, a side surface of the gate semiconductor layer 152 may be coplanar with a side surface of the gate electrode 155. However, embodiments are not limited thereto, and the gate semiconductor layer 152 may partially overlap the gate electrode 155. For example, a side surface of the gate semiconductor layer 152 may between side surfaces of the gate electrode 155.

The gate semiconductor layer 152 may include one or more materials selected from Group III-V materials, e.g., nitrides containing Al, Ga, In, B, or a combination thereof. The gate semiconductor layer 152 may be AlₓIn_{y}Ga_{1-x-y}N(0≤x≤1, 0≤y≤1, and x+y≤1). For example, the gate semiconductor layer 152 may include AlN, GaN, InN, InGaN, AlGaN, AlInN, AlInGaN, or a combination thereof. The gate semiconductor layer 152 may include a material having a different energy band gap from that of the barrier layer 136. For example, the gate semiconductor layer 152 may include GaN, and the barrier layer 136 may include AlGaN. The gate semiconductor layer 152 may be doped with a predetermined impurity. In this case, the impurity doped in the gate semiconductor layer 152 may be a p-type dopant capable of providing a hole. For example, the gate semiconductor layer 152 may include GaN doped with p-type impurities. That is, the gate semiconductor layer 152 may be made of a p-GaN layer. Embodiments are not limited thereto, and the gate semiconductor layer 152 may be a p-AlGaN layer.

A depletion region DPR may be formed within the channel layer 132 by the gate semiconductor layer 152. The depletion region DPR may be positioned within the drift region DTR, and may have a narrower width than the drift region DTR. As the gate semiconductor layer 152 having a different energy band gap from that of the barrier layer 136 is disposed on the barrier layer 136, a level of an energy band of a portion of the barrier layer 136 that overlaps the gate semiconductor layer 152 may increase. Accordingly, the depletion region DPR may be formed in a region of the channel layer 132 that overlaps the gate semiconductor layer 152. The depletion region DPR may be a region in a channel path of the channel layer 132 where the two-dimensional electron gas 134 is not formed, or may have a lower electron concentration than remaining regions. That is, the depletion region DPR may indicate a region where a flow of the two-dimensional electron gas 134 is interrupted within the drift region DTR. As the depletion region DPR occurs, a current does not flow between the source electrode 170 and the drain electrode 190, and the channel path may be blocked. Accordingly, the semiconductor device 100 according to an embodiment may have a normally off characteristic.

That is, the semiconductor device 100 according to an embodiment may be a normally-off high electron mobility transistor (HEMT). As illustrated in FIG. 2, in a normal state in which no voltage is applied to the gate electrode 155, the depletion region DPR may exist, and the semiconductor device 100 according to an embodiment may be in an off state. As illustrated in FIG. 3, when a higher voltage than the threshold voltage is applied to the gate electrode 155, the depletion region DPR may disappear, and the two-dimensional electron gas 134 may be connected without being disconnected within the drift region DTR. In this regard, the two-dimensional electron gas 134 may extend continuously from the source electrode 170 to the drain electrode 190. That is, two-dimensional electron gas 134 may be formed throughout a channel path between the source electrode 170 and the drain electrode 190, and the semiconductor device 100 according to an embodiment may be in an on state. In summary, the semiconductor device 100 according to an embodiment may include semiconductor layers with different electrical polarization characteristics, and a semiconductor layer with a relatively large polarization may induce the two-dimensional electron gas 134 in another semiconductor layer that is heterogeneously bonded therewith. This two-dimensional electron gas 134 may be used as a channel between the source electrode 170 and the drain electrode 190, and continuation or interruption of a flow of this two-dimensional electron gas 134 may be controlled by a bias voltage applied to the gate electrode 155. In a gate off state, the flow of the two-dimensional electron gas 134 may be blocked, so a current may not flow between the source electrode 170 and the drain electrode 190. As the two-dimensional electron gas 134 continues to flow in a gate on state, a current may flow between the source electrode 170 and the drain electrode 190.

Although a case where the semiconductor device 100 according to an embodiment is a normally off high electron mobility transistor has been described above, embodiments are not limited thereto. For example, the semiconductor device 100 according to an embodiment may be a normally-on high electron mobility transistor. In a case of a normally-on high electron mobility transistor, the gate semiconductor layer 152 may be omitted, and thus the gate electrode 155 may be positioned directly on the barrier layer 136. That is, the gate electrode 155 may come into contact with the barrier layer 136. In this structure, the two-dimensional electron gas 134 may be used as a channel while no voltage is applied to the gate electrode 155, and a current flow may occur between the source electrode 170 and the drain electrode 190. Additionally, when a negative voltage is applied to the gate electrode 155, the depletion region DPR in which the flow of two-dimensional electron gas 134 is interrupted may occur at a lower portion of the gate electrode 155.

The seed layer 121, the superlattice layer 124, the high-resistance layer 126, the channel layer 132, the barrier layer 136, and the gate semiconductor layer 152 described above may be sequentially stacked on the substrate 110. In the semiconductor device 100 according to an embodiment, at least one of the seed layer 121, the superlattice layer 124, the high-resistance layer 126, the channel layer 132, the barrier layer 136, or the gate semiconductor layer 152 may be omitted. The seed layer 121, the superlattice layer 124, the high-resistance layer 126, the channel layer 132, the barrier layer 136, and the gate semiconductor layer 152 may be formed of a same base semiconductor material, and the material composition ratio of each layer may be different in consideration of a role of each layer, performance required for the semiconductor device 100, etc.

The semiconductor device 100 according to an embodiment may further include a protective layer 140 positioned on the barrier layer 136.

The protective layer 140 may be positioned on the barrier layer 136 and the gate electrode 155. The protective layer 140 may cover an upper surface and a side surface of the gate electrode 155 and a side surface of the gate semiconductor layer 152. Accordingly, the barrier layer 136, the gate semiconductor layer 152, and the gate electrode 155 may be protected by the protective layer 140. However, embodiments are not limited thereto, and the gate electrode 155 may extend through the protective layer 140 to be connected to the gate semiconductor layer 152, and the protective layer 140 may not cover an upper surface of the gate electrode 155. Alternatively, a lower surface of the protective layer 140 may be in contact with the gate semiconductor layer 152. The protective layer 140 may include an insulating material. For example, the protective layer 140 may include an oxide such as SiO₂ or Al₂O₃. As another example, the protective layer 140 may also include a nitride such as SiN or an acid nitride such as SiON.

A protective layer 140 of the semiconductor device 100 according to an embodiment may include a first protective layer 141 positioned on the barrier layer 136 and a second protective layer 142 positioned on the first protective layer 141.

The first protective layer 141 may be positioned on the barrier layer 136 and the gate electrode 155. The first protective layer 141 may cover an upper surface and a side surface of the gate electrode 155 and a side surface of the gate semiconductor layer 152. The first protective layer 141 may be conformally positioned on an upper surface and a side surface of the gate electrode 155 and a side surface of the gate semiconductor layer 152. A lower surface of the first protective layer 141 may be in contact with the barrier layer 136 and the gate electrode 155. The second protective layer 142 may be positioned on the first protective layer 141. The second protective layer 142 may be conformally positioned on the first protective layer 141. The first protective layer 141 and the second protective layer 142 may include a same material, or may include different materials.

In FIG. 2 to FIG. 4, the protective layer 140 is depicted as including two layers, but embodiments are not limited thereto. For example, the protective layer 140 may be formed to include a single layer or three or more multilayers.

The source electrode 170 and the drain electrode 190 are positioned on the channel layer 132. The source electrode 170 and the drain electrode 190 may be in direct contact with the channel layer 132, and may be electrically connected to the channel layer 132.

The source electrode 170 and the drain electrode 190 may extend in the second direction (Y direction). The source electrode 170 and the drain electrode 190 may be spaced apart from each other, and the gate electrode 155 and the gate semiconductor layer 152 may be disposed between the source electrode 170 and the drain electrode 190. The gate electrode 155 and the gate semiconductor layer 152 may be spaced apart from the source electrode 170 and the drain electrode 190. For example, the source electrode 170 may be electrically connected to the channel layer 132 at a first side of the gate electrode 155, and the drain electrode 190 may be electrically connected to the channel layer 132 at a second side of the gate electrode 155. The source electrode 170 and drain electrode 190 may be positioned outside the drift region DTR of the channel layer 132. A boundary between the source electrode 170 and the channel layer 132 may be a first edge of the drift region DTR. As such, a boundary between the drain electrode 190 and the channel layer 132 may be a second edge of the drift region DTR.

The source electrode 170 and the drain electrode 190 may be positioned within a trench that recesses an upper surface of the channel layer 132. Specifically, trenches that extend through the protective layer 140 and the barrier layer 136 and recesses the upper surface of the channel layer 132 may be respectively positioned at opposite sides of the gate electrode 155 to be spaced apart from each other. The source electrode 170 and the drain electrode 190 may be positioned in the trenches positioned at opposite sides of the gate electrode 155, respectively. The source electrode 170 and the drain electrode 190 can be formed to fill insides of the trenches. Within the trenches, the source electrode 170 and the drain electrode 190 may be in contact with the channel layer 132 and the barrier layer 136. The channel layer 132 may form a bottom surface and sidewalls of the trench, and the barrier layer 136 may form sidewalls of the trench. Accordingly, the source electrode 170 and the drain electrode 190 may contact upper and side surfaces of the channel layer 132. In addition, the source electrode 170 and the drain electrode 190 may be in contact with a side surface of the barrier layer 136. That is, the source electrode 170 and the drain electrode 190 may cover side surfaces of the channel layer 132 and the barrier layer 136. However, embodiments are not limited thereto, and the channel layer 132 may not be recessed, and the source electrode 170 and the drain electrode 190 may be in contact with the channel layer 132.

In an embodiment, upper surfaces of the source electrode 170 and the drain electrode 190 may protrude beyond an upper surface of the protective layer 140. The source electrode 170 and the drain electrode 190 may cover at least a portion of the side surface of the protective layer 140. However, embodiments are not limited thereto, and the source electrode 170 and the drain electrode 190 may cover at least a portion of a side surface of the protective layer 140, and may not cover a remaining portion of the side surface of the protective layer 140. In this case, the remaining portion of the protective layer 140 may be positioned on upper surfaces of the source electrode 170 and the drain electrode 190.

The source electrode 170 and the drain electrode 190 may include a conductive material. For example, the source electrode 170 and the drain electrode 190 may include a metal, a metal alloy, a conductive metal nitride, a metal silicide, a doped semiconductor material, a conductive metal oxide, or a conductive metal nitride. For example, the source electrode 170 and the drain electrode 190 may include a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride. (TiAlN), a tantalum aluminum nitride (TaAlN), a tungsten nitride (WN), ruthenium (Ru), titanium aluminum (TiAl), a titanium aluminum carbonizationnitride (TiAlC—N), a titanium aluminum carbide (TiAlC), a titanium carbide (TiC), a tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), a molybdenum nitride (MoN), molybdenum carbide (MoC), a tungsten carbide (WC), rhodium (Rh), palladium (Pd), iridium (Ir), osmium (Os), silver (Ag), gold (Au), zinc (Zn), vanadium (V), or a combination thereof, but embodiments are not limited thereto. The source electrode 170 and the drain electrode 190 may be formed as a single layer or a multilayer. The source electrode 170 and the drain electrode 190 may be in ohmic contact with the channel layer 132. A region in contact with the source electrode 170 and the drain electrode 190 within the channel layer 132 may be doped at a relatively high concentration compared to other regions.

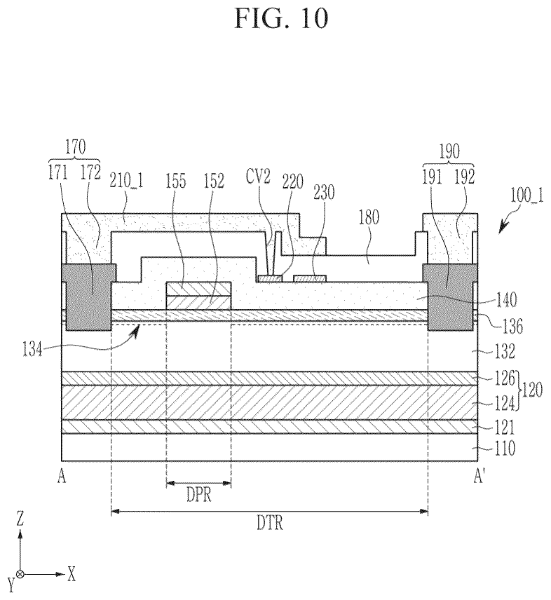

In FIGS. 2 and 3, the semiconductor device 100 according to an embodiment is illustrated as including a pair of source electrode 170 and drain electrode 190, but numbers of source electrodes 170 and drain electrodes 190 are not limited thereto. For example, the source electrode 170 may include a plurality of source electrodes sequentially stacked in the third direction (Z direction) on the channel layer 132, and the drain electrode 190 may include a plurality of drain electrodes sequentially stacked in the third direction (Z direction) on the channel layer 132. This will be described later with reference to FIG. 10.

A first field dispersion layer 210 may be disposed between the source electrode 170 and the drain electrode 190. The first field dispersion layer 210 may be positioned on the barrier layer 136. The first field dispersion layer 210 may be positioned on the protective layer 140, which is positioned on the barrier layer 136. For example, the first field dispersion layer 210 may be positioned on the second protective layer 142. The first field dispersion layer 210 may overlap the channel layer 132 in the third direction (Z direction). In an embodiment, the first field dispersion layer 210 may overlap the gate electrode 155 and the gate semiconductor layer 152 in the third direction (Z direction), but embodiments are not limited thereto.

The first field dispersion layer 210 may be electrically connected to the source electrode 170. In addition, the first field dispersion layer 210 may be electrically connected to the second field dispersion layer 220, which will be described later, through a first via CV1 extending through the second protective layer 142. The first field dispersion layer 210 may be positioned apart from the third field dispersion layer 230, which will be described later. The first field dispersion layer 210 may not be electrically connected to (i.e., may be electrically isolated from) the third field dispersion layer 230.

The first field dispersion layer 210 may be positioned between the gate electrode 155 and the drain electrode 190. For example, the channel layer 132 may include a first region AR1 that overlaps the first field dispersion layer 210 in the third direction (Z direction) between the gate electrode 155 and the drain electrode 190, and a second region AR2 that does not overlap the first field dispersion layer 210 in the third direction (Z direction). The first field dispersion layer 210 may be positioned in the first region AR1, and may not be positioned in the second region AR2. The first field dispersion layer 210 may extend from a first side of the gate electrode 155 toward the drain electrode 190. Accordingly, at least a portion of the channel layer 132 positioned between the gate electrode 155 and the drain electrode 190 may overlap the first field dispersion layer 210 in the third direction (Z direction). Herein, the third direction (Z direction) may indicate a thickness direction and a vertical direction of the channel layer 132.

The first field dispersion layer 210 may include a side surface 210_S facing the drain electrode 190. The side surface 210_S of the first field dispersion layer 210 may face a side surface of the drain electrode 190. The side surface 210_S of the first field dispersion layer 210 may correspond to a boundary between the first region AR1 and the second region AR2. In an embodiment, the side surface 210_S of the first field dispersion layer 210 may have a first surface roughness. The first surface roughness may be defined by a degree of unevenness, grooves, etc., present on the side surface 210_S of the first field dispersion layer 210. For example, as a maximum length of a protrusion from a baseline of the surface, a deviation of the length of the protrusion existing on the surface, etc., are large, the surface roughness may be large. In an embodiment, the first surface roughness of the side surface 210_S of the first field dispersion layer 210 may be due to the properties of the conductive material constituting the first field dispersion layer 210.

The first field dispersion layer 210 may include a same material as that of the source electrode 170. The first field dispersion layer 210 may include a conductive material. For example, the first field dispersion layer 210 may include a metal, a metal alloy, a conductive metal nitride, a metal silicide, a doped semiconductor material, a conductive metal oxide, or a conductive metal nitride. The first field dispersion layer 210 may be positioned in a same layer as at least a portion of the source electrode 170. For example, a portion of the source electrode 170 positioned on the second protective layer 142 may be positioned in a same layer as the first field dispersion layer 210. The first field dispersion layer 210 may be formed together in a same process as that of the source electrode 170. The first field dispersion layer 210 may be formed integrally with the source electrode 170. However, embodiments are not limited thereto, and the first field dispersion layer 210 may be positioned in a different layer from that of the source electrode 170, and may be formed in a different process.

The first field dispersion layer 210 may serve to distribute an electric field concentrated around the gate electrode 155. Specifically, in a gate-off state, a two-dimensional electron gas 134 may be positioned at a very high concentration in a portion of the channel layer 132 positioned between the gate electrode 155 and the source electrode 170, and in another portion of the channel layer 132 positioned between the gate electrode 155 and the drain electrode 190. In this case, an electric field may be concentrated on the gate electrode 155 or the gate semiconductor layer 152. The gate electrode 155 and the gate semiconductor layer 152 may be vulnerable to electric fields, and when the electric field is concentrated, a leakage current may increase and a breakdown voltage of the semiconductor device 100 may decrease. According to an embodiment, the first field dispersion layer 210 of the semiconductor device 100 may be positioned in the first region AR1 of the channel layer 132, so the electric field concentrated around the gate electrode 155 or the gate semiconductor layer 152 may be dispersed, thereby reducing the leakage current and increasing the breakdown voltage.

As illustrated in FIG. 4, the first field dispersion layer 210 of the semiconductor device 100 according to an embodiment may include a first portion 210_P1 to a third portion 210_P3.

The first portion 210_P1 may cover the gate electrode 155. For example, the first portion 210_P1 may be positioned on the second protective layer 142 and overlap the gate electrode 155 and the gate semiconductor layer 152 in the third direction (Z direction). The second portion 210_P2 may extend from a first side of the first portion 210_P1 toward the drain electrode 190. The second portion 210_P2 may be positioned on the second protective layer 142, and may overlap a second field dispersion layer 220 and a third field dispersion layer 230 to be described later in the third direction (Z direction). The second portion 210_P2 may not overlap (i.e., may be offset from) with the gate electrode 155 and the gate semiconductor layer 152 in the third direction (Z direction). The second portion 210_P2 may include a side surface facing the drain electrode 190. In an embodiment, the first portion 210_P1 and the second portion 210_P2 may be formed integrally. The first portion 210_P1 and the second portion 210_P2 may include a same material.

The third portion 210_P3 may be positioned within the first via CV1 that extends through the second protective layer 142 to expose the second protective layer 142. The third portion 210_P3 may fill the first via CV1. The third portion 210_P3 may overlap the second field dispersion layer 220 to be described later in the third direction (Z direction). The first field dispersion layer 210 and the second field dispersion layer 220, which will be described later, may be electrically connected by the third portion 210_P3. In an embodiment, the third portion 210_P3 may be formed integrally with the first portion 210_P1 and the second portion 210_P2. The third portion 210_P3 may include a same material as that of the first portion 210_P1 and the second portion 210_P2. However, embodiments are not limited thereto, the third portion 210_P3 may include a different material from that of the first portion 210_P1 and the second portion 210_P2, and may be formed separately in a different process.

In an embodiment, a number of first field dispersion layers 210 may be varied. For example, the first field dispersion layer 210 may include a plurality of first field dispersion layers positioned on the second protective layer 142.

The second field dispersion layer 220 may be positioned between the source electrode 170 and the drain electrode 190. The second field dispersion layer 220 may be positioned between the gate electrode 155 and the drain electrode 190. The second field dispersion layer 220 may be positioned apart from the gate electrode 155 and the gate semiconductor layer 152 along the first direction (X direction). Accordingly, the second field dispersion layer 220 may not overlap (i.e., may be offset from) the gate electrode 155 and the gate semiconductor layer 152 along the third direction (Z direction). In addition, the second field dispersion layer 220 may be positioned apart from the drain electrode 190 along the first direction (X direction). The second field dispersion layer 220 may be positioned in the first region AR1 of the channel layer 132. That is, the second field dispersion layer 220 may be positioned on a lower surface of the first field dispersion layer 210. The second field dispersion layer 220 may overlap the first field dispersion layer 210 in the third direction (Z direction). For example, the second field dispersion layer 220 may completely overlap the first field dispersion layer 210 in the third direction (Z direction).

The second field dispersion layer 220 may be positioned on the barrier layer 136. The second field dispersion layer 220 may be positioned on the protective layer 140, which is positioned on the barrier layer 136. For example, the second field dispersion layer 220 may be positioned between the first protective layer 141 and the second protective layer 142. The second field dispersion layer 220 may be positioned between the first protective layer 141 and the first field dispersion layer 210. A thickness of the second field dispersion layer 220 along the third direction (Z direction) may be smaller than or equal to a second thickness TH2 of the first field dispersion layer 210 along the third direction (Z direction).

In an embodiment, an upper surface of the second field dispersion layer 220 may be positioned at a level lower than that of the upper surface of the gate electrode 155. That is, an upper surface of the second field dispersion layer 220 may be positioned closer to an upper surface of the channel layer 132 than to an upper surface of the gate electrode 155. At least a portion of the second field dispersion layer 220 may overlap the gate electrode 155 in the first direction (X direction), but embodiments are not limited thereto.

In an embodiment, a lower surface of the second field dispersion layer 220 may be positioned at a higher level than that of a lower surface of the gate semiconductor layer 152. That is, the lower surface of the second field dispersion layer 220 may be positioned further from the upper surface of the channel layer 132 than the lower surface of the gate semiconductor layer 152. This may be due to a process characteristic of forming a first protective layer 141 after patterning the gate semiconductor layer 152 and the gate electrode 155, and forming a second field dispersion layer 220 on the first protective layer 141 so as to be spaced apart from the gate electrode 155 and the gate semiconductor layer 152 along the first direction (X direction). In an embodiment, the upper surface of the second field dispersion layer 220 may be positioned at a higher level than that of the upper surface of the gate semiconductor layer 152. That is, the upper surface of the second field dispersion layer 220 may be positioned further from the upper surface of the channel layer 132 than the upper surface of the gate semiconductor layer 152, but embodiments are not limited thereto.

In an embodiment, the second field dispersion layer 220 may be electrically connected to the first field dispersion layer 210. For example, the second field dispersion layer 220 may be electrically connected to the first field dispersion layer 210 through the first via CV1 extending through the second protective layer 142, but embodiments are not limited thereto.

The second field dispersion layer 220 may include a conductive material. The second field dispersion layer 220 may include a different material from that of the first field dispersion layer 210. For example, the second field dispersion layer 220 may include TiN. However, embodiments are not limited thereto, as another example, the second filed dispersion layer 220 may include a metal, a metal alloy, a conductive metal nitride, a metal silicide, a doped semiconductor material, a conductive metal oxide, or a conductive metal nitride.

The third field dispersion layer 230 may be positioned between the second field dispersion layer 220 and the drain electrode 190. The third field dispersion layer 230 may be positioned between the gate electrode 155 and the drain electrode 190. The third field dispersion layer 230 may be positioned apart from the gate electrode 155 and the gate semiconductor layer 152 along the first direction (X direction). Accordingly, the third field dispersion layer 230 may not overlap (i.e., may be offset from) the gate electrode 155 and the gate semiconductor layer 152 along the third direction (Z direction). In addition, the third field dispersion layer 230 may positioned apart from the second field dispersion layer 220 along the first direction (X direction). In addition, the third field distribution layer 230 may be positioned apart from the drain electrode 190 along the first direction (X direction). In an embodiment, the third field dispersion layer 230 may indicate a field dispersion layer positioned between the barrier layer 136 and the first field dispersion layer 210 and between the second field dispersion layer 220 and the drain electrode 190.

In an embodiment, a single third field dispersion layer 230 may be provided. The single third field dispersion layer 230 may extend in the second direction (Y direction) in a plan view. The third field dispersion layer 230 may extend from a first edge of the semiconductor device to a second edge of the semiconductor device in the second direction (Y direction). The third field dispersion layer 230 may be extended parallel to the second field dispersion layer 220, but embodiments are not limited thereto. The single third field dispersion layer 230 may be positioned between the second field dispersion layer 220 and the drain electrode 190. However, embodiments are not limited thereto, and a plurality of third field dispersion layers 230 may be provided to be arranged along the second direction (Y direction). Alternatively, the third field dispersion layers 230 may be provided to be arranged along the first direction (X direction).

The third field dispersion layer 230 may overlap the first field dispersion layer 210 in the third direction (Z direction). For example, the third field dispersion layer 230 may completely overlap the first field dispersion layer 210 in the third direction (Z direction). The third field dispersion layer 230 may be positioned on a lower surface of the first field dispersion layer 210. In an embodiment, the third field dispersion layer 230 may be positioned in the first region AR1 of the channel layer 132, and may not be positioned in the second region AR2. That is, the third field dispersion layer 230 may be positioned in the first region AR1 of the channel layer 132.

The first field dispersion layer 230 may include a side surface 230_S facing the drain electrode 190. The side surface 230_S of the third field dispersion layer 230 may face a side surface of the drain electrode 190. For example, as shown in FIG. 4, when a single third field dispersion layer 230 is provided, the side surface 230_S of the third field dispersion layer 230 may be an edge of the third field dispersion layer 230. Hereinafter, the side surface 230_S of the third field dispersion layer 230 may refer to an edge of the third field dispersion layer 230 singly provided.

In an embodiment, the side surface 230_S of the third field dispersion layer 230 may have a second surface roughness that is less than or equal to the first surface roughness. The second surface roughness may be defined by a degree of unevenness, grooves, etc., present on the side surface 230_S of the third field dispersion layer 230. For example, as a maximum length of a protrusion from a baseline of the surface, a deviation of the length of the protrusion existing on the surface, etc., are large, the surface roughness may be large. In an embodiment, the side surface 230_S of the third field dispersion layer 230 may have a smaller surface roughness than that of the side surface 210_S of the first field dispersion layer 210. For example, the side surface 230_S of the third field dispersion layer 230 may have a smaller ratio of an area of unevenness or grooves per unit area than that of the side surface 210_S of the first field dispersion layer 210. As another example, the side surface 230_S of the third field dispersion layer 230 may have a smaller maximum protrusion length of the unevenness compared to the side surface 210_S of the first field dispersion layer 210. A second surface roughness of the side surface 230_S of the third field dispersion layer 230 may be due to properties of a conductive material constituting the third field dispersion layer 230.

An edge of the third field dispersion layer 230 may be aligned with an edge of the first field dispersion layer 210. For example, when a single third field dispersion layer 230 is provided, the edge of the third field dispersion layer 230 may indicate the side surface 230_S of the third field dispersion layer 230. The side surface 230_S of the third field dispersion layer 230 may be aligned with the side surface 210_S of the first field dispersion layer 210 and a reference axis AX. Herein, the reference axis AX may indicate an axis extending in the third direction (Z direction) from the side surface 210_S of the first field dispersion layer 210 on a cross-section formed in the first direction (X direction) and the third direction (Z direction).

Accordingly, a distance from a side surface of the gate electrode 155 to the side surface 230_S of the third field dispersion layer 230 may be substantially equal to a distance from a side surface of the gate electrode 155 to the side surface 210_S of the first field dispersion layer 210. In addition, a distance along the first direction (X direction) between the drain electrode 190 and the third field dispersion layer 230 may be substantially equal to a distance along the first direction (X direction) between the drain electrode 190 and the first field dispersion layer 210.

In an embodiment, a distance along the first direction (X direction) between the third field dispersion layer 230 and the drain electrode 190 may be greater than or equal to a distance along the first direction (X direction) between the third field dispersion layer 230 and the gate electrode 155. In an embodiment, a distance along the first direction (X direction) between the side surface of the gate electrode 155 and the side surface 210_S of the first field dispersion layer 210 may be less than or equal to a distance along the first direction (X direction) between the side surface 230_S of the third field dispersion layer 230 and the side surface of the drain electrode 190. In this case, a first width W1 of the third field dispersion layer 230 along the first direction (X direction) may be 180 nm to 350 nm. In this range, the third field dispersion layer 230 may be sufficiently spaced from the second field dispersion layer 220 and easily aligned with the side surface 210_S of the first field dispersion layer 210.

The third field dispersion layer 230 may be positioned in a same layer as that of the second field dispersion layer 220. For example, the third field dispersion layer 230 and the second field dispersion layer 220 may be positioned between the first protective layer 141 and the second protective layer 142. The third field dispersion layer 230 and the second field dispersion layer 220 may be positioned between the barrier layer 136 and the first field dispersion layer 210.

In an embodiment, an upper surface of the third field dispersion layer 230 may be positioned at a level lower than that of the upper surface of the gate electrode 155. That is, an upper surface of the third field distribution layer 230 may be positioned closer to an upper surface of the channel layer 132 than to an upper surface of the gate electrode 155. At least a portion of the third field distribution layer 230 may overlap the gate electrode 155 in the first direction (X direction), but embodiments are not limited thereto.

In an embodiment, a lower surface of the third field distribution layer 230 may be positioned at a higher level than that of a lower surface of the gate semiconductor layer 152. That is, the lower surface of the third field dispersion layer 230 may be positioned further from the upper surface of the channel layer 132 than the lower surface of the gate semiconductor layer 152. This may be due to a process characteristic of forming a first protective layer 141 after patterning the gate semiconductor layer 152 and the gate electrode 155, and forming a third field dispersion layer 230 on the first protective layer 141 so as to be spaced apart from the gate electrode 155 and the gate semiconductor layer 152 along the first direction (X direction). In an embodiment, the upper surface of the third field distribution layer 230 may be positioned at a higher level than that of the upper surface of the gate semiconductor layer 152. That is, the upper surface of the third field distribution layer 230 may be positioned further from the upper surface of the channel layer 132 than the upper surface of the gate semiconductor layer 152, but embodiments are not limited thereto. A thickness TH1 of the third field dispersion layer 230 along the third direction (Z direction) may be smaller than or equal to a second thickness TH2 of the first field dispersion layer 210 along the third direction (Z direction).

In an embodiment, the third field distribution layer 230 may be floating. For example, the third field distribution layer 230 may not connected to ground or other voltage source.

The third field distribution layer 230 may include a conductive material. The third field dispersion layer 230 may include a same material as that of the second field dispersion layer 220. The third field dispersion layer 230 may include a different material from that of the first field dispersion layer 210. For example, the third field dispersion layer 230 may include TiN. However, embodiments are not limited thereto, as another example, the third filed distribution layer 230 may include a metal, a metal alloy, a conductive metal nitride, a metal silicide, a doped semiconductor material, a conductive metal oxide, or a conductive metal nitride.

When the side surface 210_S of the first field dispersion layer 210 of the semiconductor device 100 according to an embodiment has a first surface roughness, an electric field concentrated around the gate electrode 155 or the gate semiconductor layer 152 may not be effectively dispersed. As the side surface 230_S of the third field dispersion layer 230 of the semiconductor device 100 according to an embodiment is aligned with the side surface 210_S of the first field dispersion layer 210, an electric field concentrated around the gate electrode 155 or the gate semiconductor layer 152 may be effectively dispersed, and reliability of the semiconductor device 100 according to an embodiment may be improved.

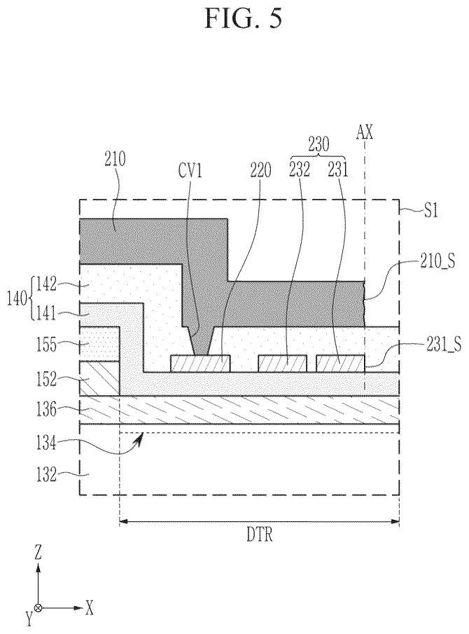

Hereinafter, a semiconductor device according to some embodiments will be described with reference to FIG. 5 to FIG. 9.

FIG. 5 to FIG. 9 illustrate top plan views corresponding to a region S1 in FIG. 1, showing semiconductor devices according to some embodiments.

FIGS. 5 to 9 illustrate various modified examples of semiconductor devices according to embodiments illustrated in FIGS. 1 to 4. The modified examples illustrated in FIG. 5 to FIG. 9 are substantially equivalent to those illustrated in FIG. 1 to FIG. 4, so a description thereof will be omitted and differences therebetween will be mainly described. In addition, same reference numerals are used for same components.

Referring to FIG. 5, a plurality of third field distribution layers 230 of the semiconductor device according to some embodiments may be provided. For example, the third field dispersion layer 230 may include a first pattern portion 231 positioned on a first side of the second field dispersion layer 220 and a second pattern portion 232 positioned between the second field dispersion layer 220 and the first pattern portion 231.

The first pattern portion 231 and the second pattern portion 232 may be spaced apart from each other along the first direction (X direction). The first pattern portion 231 and the second pattern portion 232 may overlap the first field dispersion layer 210 in the third direction (Z direction). For example, the first pattern portion 231 and the second pattern portion 232 may completely overlap the first field dispersion layer 210 in the third direction (Z direction). The first pattern portion 231 and the second pattern portion 232 may be positioned in the first region AR1 (FIG. 2) of the channel layer 132.

In some embodiments, as the third field dispersion layer 230 includes a plurality of pattern portions 231 and 232, an edge of the third field dispersion layer 230 may be defined as a side surface 231_S of the first pattern portion 231. For example, an edge of the third field dispersion layer 230 may indicate the side surface 231_S of the first pattern portion 231 facing the drain electrode 190.

In some embodiments, the side surface 231_S of the first pattern portion 231 may have a second surface roughness that is less than or equal to the first surface roughness. The side surface 231_S of the first pattern portion 231 may be aligned with the side surface 210_S of the first field dispersion layer 210. The description of this is substantially the same as the description of the third field dispersion layer 230 of embodiments shown in FIGS. 1 to 4, and accordingly will be omitted.

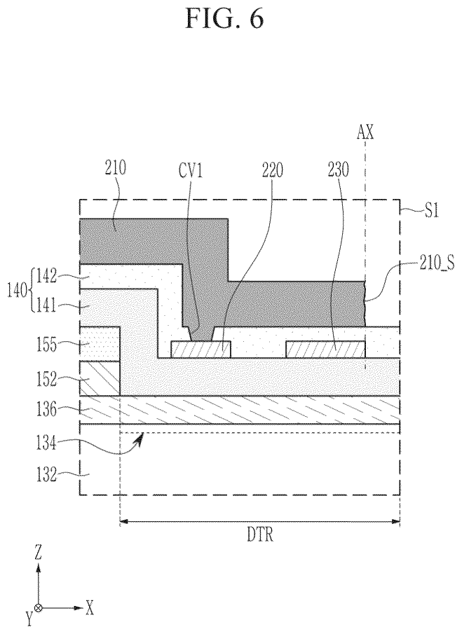

Referring to FIG. 6, the second field dispersion layer 220 and the third field dispersion layer 230 of the semiconductor device according to some embodiments may not overlap the gate semiconductor layer 152 in the first direction (X direction). For example, a lower surface of the second field dispersion layer 220 and a lower surface of the third field dispersion layer 230 may be positioned at a higher level than that of an upper surface of the gate semiconductor layer 152. That is, a lower surface of the second field dispersion layer 220 and a lower surface of the third field dispersion layer 230 may be positioned further from an upper surface of the channel layer 132 than an upper surface of the gate semiconductor layer 152. This is because a thickness of the first protective layer 141 along the third direction (Z direction) is greater than a thickness of the gate semiconductor layer 152 along the third direction (Z direction).

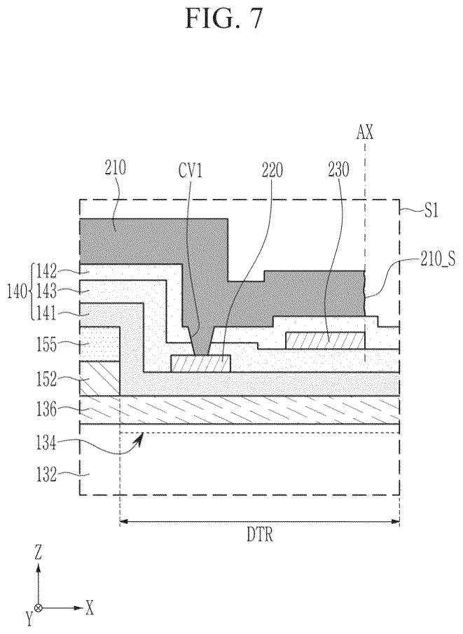

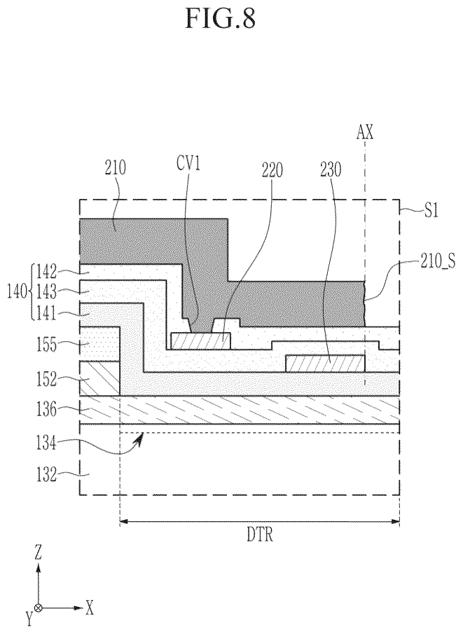

Referring to FIGS. 7 and 8, a semiconductor device according to some embodiments may further include a third protective layer 143 positioned between the first protective layer 141 and the second protective layer 142.

The third protective layer 143 may be positioned on the first protective layer 141. The third protective layer 143 may include an insulating material. The third protective layer 143 may include the same material as the first protective layer 141 and the second protective layer 142, but embodiments are not limited thereto. For example, the third protective layer 143 may include an oxide such as SiO₂ or Al₂O₃. As another example, the third protective layer 143 may also include a nitride such as SiN or an acid nitride such as SiON.

In some embodiments, the second field dispersion layer 220 and the third field dispersion layer 230 may be positioned in different layers.

For example, as illustrated in FIG. 7, the second field dispersion layer 220 may be positioned between the first protective layer 141 and the third protective layer 143, and the third field dispersion layer 230 may be positioned between the third protective layer 143 and the second protective layer 142. Accordingly, a lower surface of the third field dispersion layer 230 may be positioned at a higher level than that of the lower surface of the second field dispersion layer 220. The lower surface of the third field dispersion layer 230 may be positioned further from the upper surface of the channel layer 132 than the lower surface of the second field dispersion layer 220. Additionally, the upper surface of the third field dispersion layer 230 may be positioned at a higher level than that of the upper surface of the second field dispersion layer 220. The upper surface of the third field dispersion layer 230 may be positioned further from the upper surface of the channel layer 132 than the upper surface of the second field dispersion layer 220.

As another example, as illustrated in FIG. 8, the second field dispersion layer 220 may be positioned between the third protective layer 143 and the second protective layer 142, and the third field dispersion layer 230 may be positioned between the first protective layer 141 and the third protective layer 143. Accordingly, a lower surface of the third field dispersion layer 230 may be positioned at a lower level than that of the lower surface of the second field dispersion layer 220. The lower surface of the third field dispersion layer 230 may be positioned closer to the upper surface of the channel layer 132 than the lower surface of the second field dispersion layer 220. Additionally, the upper surface of the third field dispersion layer 230 may be positioned at a lower level than that of the upper surface of the second field dispersion layer 220. The upper surface of the third field dispersion layer 230 may be positioned closer to the upper surface of the channel layer 132 than the upper surface of the second field dispersion layer 220.

In FIG. 7 and FIG. 8, the protective layer 140 is depicted as including three layers, but embodiments are not limited thereto. For example, the protective layer 140 may be formed to include four or more multilayers.

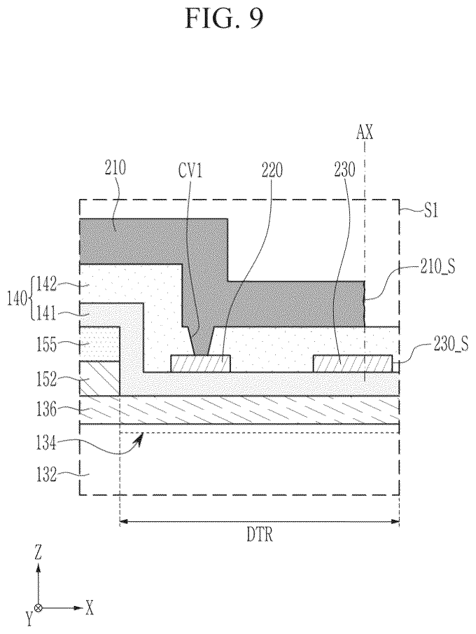

Referring to FIG. 9, at least a portion of the third field dispersion layer 230 of the semiconductor device according to some embodiments may not overlap (i.e., may be offset from) the first field dispersion layer 210 in the third direction (Z direction). In some embodiments, at least a portion of the third field dispersion layer 230 may overlap the first field dispersion layer 210 in the third direction (Z direction), and a remaining portion of the third field dispersion layer 230 may not overlap the first field dispersion layer 210 in the third direction (Z direction). The side surface 230_S of the third field dispersion layer 230 may protrude from the side surface 210_S of the first field dispersion layer 210 toward the drain electrode 190. That is, the side surface 230_S of the third field dispersion layer 230 may be positioned further from the side surface of the gate electrode 155 than the side surface 210_S of the first field dispersion layer 210.

Hereinafter, a semiconductor device according to some embodiments will be described with reference to FIG. 10.

FIG. 10 illustrates a cross-sectional view corresponding to A-A′ of FIG. 1, showing a semiconductor device according to some embodiments.

FIG. 10 illustrate various modified examples of semiconductor devices according to embodiments illustrated in FIGS. 1 to 4. FIG. 10 is similar to embodiments illustrated in FIG. 1 to FIG. 4, so a description thereof will be omitted and differences therebetween will be mainly described. In addition, same reference numerals are used for same components.

Referring to FIG. 10, a semiconductor device 100_1 according to some embodiments may further include an upper protective layer 180 positioned on the protective layer 140.

The upper protective layer 180 may be positioned on the protective layer 140, the source electrode 170, and the drain electrode 190. The upper protective layer 180 may include an insulating material. The upper protective layer 180 may include a same material as that of the protective layer 140, but embodiments are not limited thereto. For example, the upper protective layer 180 may include an oxide such as SiO₂ or Al₂O₃. As another example, the upper protective layer 180 may also include a nitride such as SiN or an acid nitride such as SiON.

According to some embodiments, a plurality of source electrodes 170 and a plurality of drain electrodes 190 of the semiconductor device 100_1 may be provided.

For example, the source electrode 170 may include a plurality of source electrodes 171 and 172 sequentially stacked in the third direction (Z direction) on the channel layer 132, and the drain electrode 190 may include a plurality of drain electrodes 191 and 192 sequentially stacked in the third direction (Z direction) on the channel layer 132. The first source electrode 171 and the first drain electrode 191 may be electrically connected to the channel layer 132 by extending through the protective layer 140 and the barrier layer 136. The second source electrode 172 may be electrically connected to the first source electrode 171 through the upper protective layer 180. Then, the second drain electrode 192 may be electrically connected to the first drain electrode 191 by extending through the upper protective layer 180.

The first field dispersion layer 210_1 of the semiconductor device 100_1 according to some embodiments may be positioned on the upper protective layer 180. The first field dispersion layer 210_1 may be formed integrally with the second source electrode 172. The first field dispersion layer 210_1 may include a same material as that of the second source electrode 172. The remaining description of the first field dispersion layer 210_1 is substantially the same as the description of the first field dispersion layer 210 of FIG. 1 to FIG. 4, so it will be omitted.

In some embodiments, the second field dispersion layer 220 and the third field dispersion layer 230 may be positioned between the protective layer 140 and the upper protective layer 180. The second field dispersion layer 220 may be electrically connected to the first field dispersion layer 210_1 through a second via CV2 extending through the upper protective layer 180. In some embodiments, the second field dispersion layer 220 may be positioned in a same layer as the third field dispersion layer 230. The lower surface of the second field dispersion layer 220 may be positioned at substantially a same level as that of the lower surface of the third field dispersion layer 230, but embodiments are not limited thereto.

In some embodiments, the lower surface of the second field distribution layer 220 may be positioned at a higher level than that of the upper surface of the gate semiconductor layer 152. The lower surface of the second field dispersion layer 220 may be positioned further from the upper surface of the channel layer 132 than the upper surface of the gate semiconductor layer 152. In addition, the lower surface of the third field distribution layer 230 may be positioned at a higher level than that of the upper surface of the gate semiconductor layer 152. The lower surface of the third field dispersion layer 230 may be positioned further from the upper surface of the channel layer 132 than the upper surface of the gate semiconductor layer 152.

In some embodiments, the lower surface of the second field distribution layer 220 may be positioned at a higher level than that of the upper surface of the gate electrode 155. The lower surface of the second field dispersion layer 220 may be positioned further from the upper surface of the channel layer 132 than the upper surface of the gate electrode 155. In addition, the lower surface of the third field distribution layer 230 may be positioned at a higher level than that of the upper surface of the gate electrode 155. The lower surface of the third field dispersion layer 230 may be positioned further from the upper surface of the channel layer 132 than the upper surface of the gate electrode 155. However, embodiments are not limited thereto, and the lower surface of the second field dispersion layer 220 and the lower surface of the third field dispersion layer 230 may be positioned at a lower level than that of the upper surface of the gate electrode 155.

A remaining description of the second field dispersion layer 220 and the third field dispersion layer 230 is substantially the same as the description of the second field dispersion layer 220 and the third field dispersion layer 230 of FIGS. 1 to 4, and accordingly will be omitted.

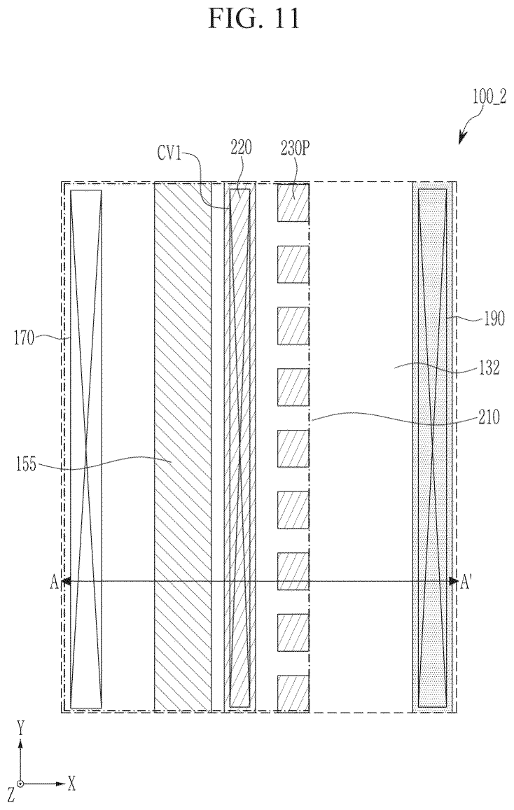

Hereinafter, a semiconductor device according to some embodiments will be described with reference to FIG. 11 to FIG. 15.

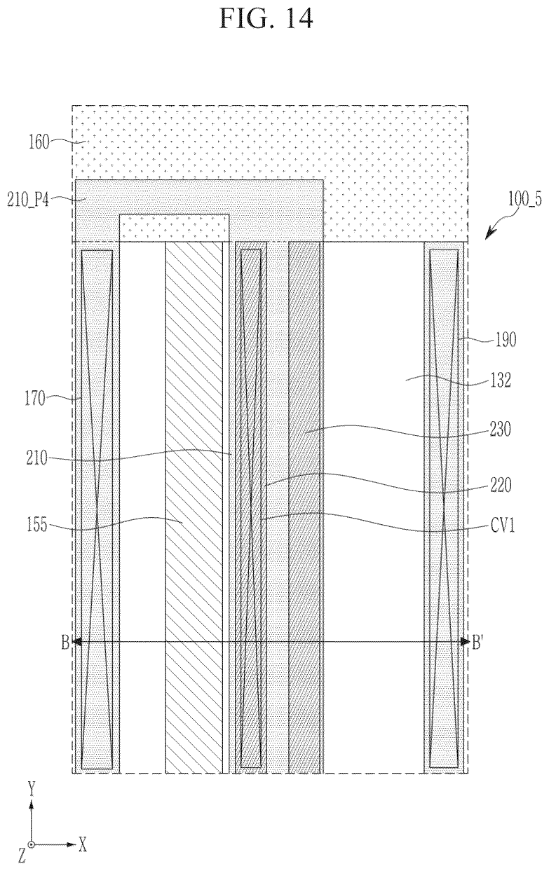

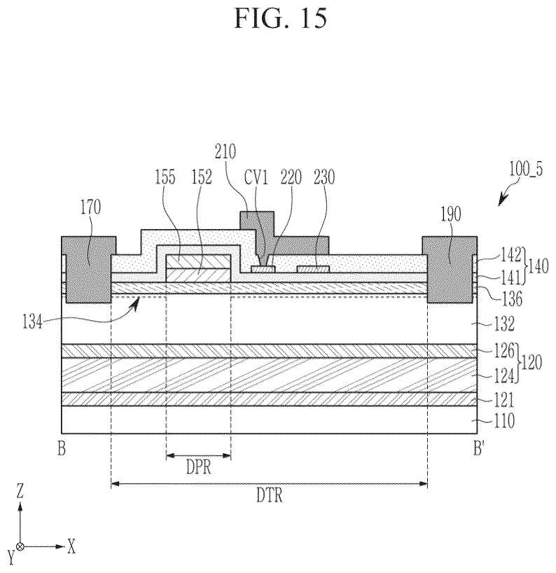

FIG. 11 to FIG. 14 each illustrate a top plan view showing a semiconductor device according to some embodiments. FIG. 15 illustrates a cross-sectional view taken along a line B-B′ of FIG. 14.

FIGS. 11 to 15 illustrate various modified examples of semiconductor devices according to embodiments. The modified examples illustrated in FIG. 11 to FIG. 15 are substantially equivalent to those illustrated in FIG. 1 to FIG. 4, so a description thereof will be omitted and differences therebetween will be mainly described. In addition, same reference numerals are used for same components.

Referring to FIG. 11, a semiconductor device 100_2 according to some embodiments may include a plurality of third field dispersion patterns 230P spaced apart from each other along the second direction (Y direction). A plurality of third field distribution patterns 230P may be positioned apart along the second direction (Y direction). The third field distribution patterns 230P may each have a rectangular shape in a plan view, but embodiments are not limited thereto. In some embodiments, a side surface of each of the third field dispersion patterns 230P facing the drain electrode 190 may be aligned with a side surface of the first field dispersion layer 210.

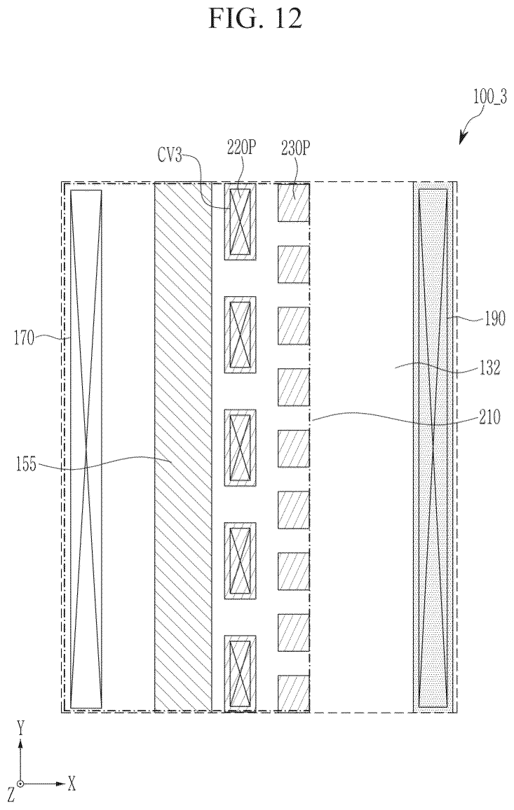

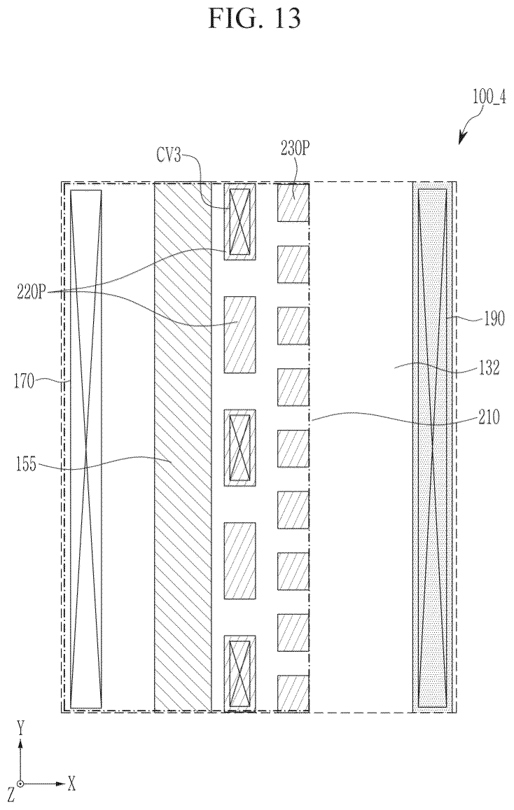

Referring to FIGS. 12 and 13, semiconductor devices 100_3 and 100_4 according to some embodiments may include a plurality of second field dispersion patterns 220P spaced apart from each other along the second direction (Y direction). A plurality of second field distribution patterns 220P may be positioned apart along the second direction (Y direction). The second field distribution patterns 220P may each have a rectangular shape in a plan view, but embodiments are not limited thereto.

In some embodiments, as shown in FIG. 12, each of the second field dispersion patterns 220P may be electrically connected to the first field dispersion layer 210 through a third via CV3. However, embodiments are not limited thereto, and as shown in FIG. 13, some of the second field dispersion patterns 220P of the semiconductor element 100_4 according to some embodiments may be electrically connected to the first field dispersion layer 210 through the third via CV3, and remaining some may not be electrically connected to (i.e., may be electrically isolated from) the first field dispersion layer 210. That is, some of the second field dispersion patterns 220P may be floating (i.e., not connected to ground or other voltage source).

Referring to FIGS. 14 and 15, a semiconductor device 100_5 according to some embodiments may further include a separation structure 160 positioned at a first side of the channel layer 132.

The separation structure 160 may be positioned at a first side of the channel layer 132 in the second direction (Y direction), but embodiments are not limited thereto. In some embodiments, the separation structure 160 may extend through the barrier layer 136 and the channel layer 132. For example, the separation structure 160 may recess at least a portion of the substrate 110 by extending through the barrier layer 136, the channel layer 132, the seed layer 121, and the buffer layer 120. However, embodiments are not limited thereto, and as another example, the separation structure 160 may extend through the barrier layer 136 and the channel layer 132, and may recess at least a portion of the buffer layer 120.

In some embodiments, the separation structure 160 may be formed by forming the barrier layer 136 on the channel layer 132 and performing an ion implantation process within a portion of the barrier layer 136. For example, in a region of the channel layer 132 that overlaps a region where an ion implantation process is performed in the barrier layer 136 in the third direction (Z direction), no or little two-dimensional electron gas may be formed. In this case, the ion implant region of the barrier layer 136 and a corresponding region of the channel layer 132 may correspond to the separation structure 160. As another example, the gate semiconductor layer 152 may be positioned on the barrier layer 136, and after performing an ion implant process at an upper end of the gate semiconductor layer 152, the gate semiconductor layer 152 may be patterned. Accordingly, the ion implanted region of the exposed barrier layer 136, the channel layer 132, and the buffer layer 120 may correspond to the separated structure 160. A material used in the ion implant process may be argon (Ar) ions.

However, embodiments are not limited thereto, and the separation structure 160 may be formed by forming the barrier layer 136 on the channel layer 132, forming a trench extending through the barrier layer 136, and then filling the trench with an insulating material. During a process of forming the trench, at least a portion of the channel layer 132 may be recessed as well. In this case, an insulating material constituting the separation structure 160 may include a same material as that of the protective layer 140. For example, the insulating material constituting the separation structure 160 may include an oxide such as SiO₂ or Al₂O₃. As another example, an insulating material constituting the separation structure 160 may include a nitride such as SiN or an oxynitride such as SiON. However, embodiments are not limited thereto, and the insulating material constituting the separation structure 160 may include a different material from that of the protective layer 140.

In some embodiments, a portion of the first field dispersion layer 210 may be positioned on the separation structure 160. For example, the first field dispersion layer 210 may include a portion overlapping the channel layer 132 and a fourth portion 210_P4 overlapping the separation structure 160 in the third direction (Z direction). In some embodiments, the first field dispersion layer 210 may overlap the second field dispersion layer 220 and the third field dispersion layer 230 in a third direction (Z direction) bypassing the gate electrode 155. Accordingly, the first field dispersion layer 210 may not overlap (i.e., may be offset from) the gate electrode 155 in the third direction (Z direction).

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

What is claimed is:

1. A semiconductor device comprising:
a channel layer;
a barrier layer on the channel layer, the barrier layer comprising a material having a different energy band gap from that of the channel layer;
a source electrode on the channel layer;
a drain electrode on the channel layer;
a gate electrode on the barrier layer between the source electrode and the drain electrode;
a gate semiconductor layer between the barrier layer and the gate electrode;
a first field dispersion layer between the source electrode and the drain electrode, the first field dispersion layer being connected to the source electrode;
a second field dispersion layer between the gate electrode and the drain electrode on the barrier layer, the second field dispersion layer being connected to the first field dispersion layer; and
a third field dispersion layer between the second field dispersion layer and the drain electrode on the barrier layer,
wherein an edge of the first field dispersion layer is aligned with an edge of the third field dispersion layer along a vertical direction.

2. The semiconductor device of claim 1, wherein a single third field dispersion layer extends from a first edge of the semiconductor device to a second edge of the semiconductor device, and
wherein a distance from a side surface of the gate electrode to a side surface of the first field dispersion layer is equal to a distance from a side surface of the gate electrode to a side surface of the third field dispersion layer.

3. The semiconductor device of claim 1, wherein the third field dispersion layer completely overlaps the first field dispersion layer along the vertical direction.

4. The semiconductor device of claim 3, wherein a distance along a first direction between the third field dispersion layer and the drain electrode is greater than or equal to a distance along the first direction between the third field dispersion layer and the gate electrode.

5. The semiconductor device of claim 4, wherein a distance along the first direction between a side surface of the gate electrode and a side surface of the first field dispersion layer is less than or equal to a distance along the first direction between a side surface of the third field dispersion layer and a side surface of the drain electrode.

6. The semiconductor device of claim 4, wherein a width of the third field dispersion layer along the first direction is within a range from 180 nm to 350 nm.

7. The semiconductor device of claim 1, wherein the channel layer comprises a first region that overlaps the first field dispersion layer along the vertical direction between the gate electrode and the drain electrode, and a second region that are offset from the first field dispersion layer along the vertical direction, and
wherein the third field dispersion layer overlaps the first region along the vertical direction.

8. The semiconductor device of claim 1, wherein the first field dispersion layer is formed integrally with the source electrode and comprises a same material as that of the source electrode, and
wherein the second field dispersion layer comprises a same material as that of the third field dispersion layer.

9. The semiconductor device of claim 8, wherein the third field dispersion layer comprises titanium nitride, and the first field dispersion layer comprises a different material from that of the third field dispersion layer.

10. The semiconductor device of claim 1, wherein a side surface of the first field dispersion layer has a first surface roughness, and a side surface of the third field dispersion layer has a second surface roughness that is less than or equal to the first surface roughness.

11. The semiconductor device of claim 1, wherein a thickness of the first field dispersion layer along the vertical direction is greater than a thickness of the third field dispersion layer along the vertical direction.

12. The semiconductor device of claim 1, further comprising:
a first protective layer on the barrier layer, the first protective layer at least partially covering the gate electrode; and
a second protective layer on the first protective layer,
wherein the first field dispersion layer is on the second protective layer, and
wherein the second field dispersion layer and the second field dispersion layer are between the first protective layer and the second protective layer.

13. The semiconductor device of claim 12, further comprising a third protective layer between the first protective layer and the second protective layer,
wherein the second field dispersion layer is between the first protective layer and the third protective layer, and
wherein the third field dispersion layer is between the third protective layer and the second protective layer.

14. The semiconductor device of claim 1, further comprising:
a protective layer on the barrier layer, the protective layer at least partially covering the gate electrode; and
an upper protective layer on the protective layer,
wherein the source electrode comprises:
a first source electrode on the channel layer through the protective layer; and
a second source electrode extending through the upper protective layer to the first source electrode,
wherein the first field dispersion layer is on the upper protective layer, and the first field dispersion layer comprises a same material as that of the second source electrode, and
wherein the second field dispersion layer and the third field dispersion layer are between the protective layer and the upper protective layer.

15. A semiconductor device comprising:
a channel layer;
a barrier layer on the channel layer, the barrier layer comprising a material having a different energy band gap from that of the channel layer;
a source electrode on the channel layer;
a drain electrode on the channel layer;
a gate electrode on the barrier layer, between the source electrode and the drain electrode;
a gate semiconductor layer between the barrier layer and the gate electrode;
a first field dispersion layer between the source electrode and the drain electrode, the first field dispersion layer connected to the source electrode;
a second field dispersion layer between the barrier layer and the first field dispersion layer, and between the gate electrode and the drain electrode, the second field dispersion layer connected to the first field dispersion layer; and
a third field dispersion layer between the barrier layer and the first field dispersion layer, and between the second field dispersion layer and the drain electrode,
wherein a single third field dispersion layer extends from a first edge of the semiconductor device to a second edge of the semiconductor device, and
wherein a distance between the drain electrode and the first field dispersion layer is equal to a distance between the drain electrode and the third field dispersion layer.

16. The semiconductor device of claim 15, wherein the second field dispersion layer and the third field dispersion layer completely overlap the first field dispersion layer along a vertical direction.

17. The semiconductor device of claim 15, wherein an upper surface of the third field dispersion layer is closer to an upper surface of the channel layer than to an upper surface of the gate electrode along a vertical direction.

18. The semiconductor device of claim 15, wherein the gate electrode vertically overlaps the first field dispersion layer and is offset from the second field dispersion layer and the third field dispersion layer.

19. The semiconductor device of claim 15, wherein the third field dispersion layer comprises titanium nitride, and the first field dispersion layer comprises a different material from that of the third field dispersion layer.

20. A semiconductor device comprising:
a channel layer comprising gallium nitride;
a barrier layer on the channel layer and comprising aluminum gallium nitride;
a source electrode on the channel layer;
a drain electrode on the channel layer;
a gate electrode on the barrier layer, between the source electrode and the drain electrode;
a gate semiconductor layer between the barrier layer and the gate electrode, the gate semiconductor layer comprising gallium nitride doped with a p-type impurity;
a first protective layer on the barrier layer, the first protective layer at least partially covering the gate electrode;
a second protective layer on the first protective layer;
a first field dispersion layer on the second protective layer, wherein the first field dispersion layer overlaps the gate electrode along a vertical direction, and is integrally formed with the source electrode;
a second field dispersion layer between the first protective layer and the second protective layer, wherein the second field dispersion layer overlaps the first field dispersion layer along the vertical direction and comprises titanium nitride; and
a third field dispersion layer between the first protective layer and the second protective layer, and between the second field dispersion layer and the drain electrode, wherein the third field dispersion layer comprises titanium nitride,
wherein a distance from a side surface of the gate electrode to a side surface of the first field dispersion layer is equal to a distance from a side surface of the gate electrode to a side surface of the third field dispersion layer.
